(19) United States
(12) Patent Application Publication
(10) Pub. No.: US 2007/0269751 A1
(43) Pub. Date: Nov. 22, 2007

(54) Immersion Liquid for Liquid Immersion Lithography Process and Method for Forming Resist Pattern Using Such Immersion Liquid

(76) Inventor: Kazumasa Wakiya, Kawasaki-shi (JP)

Correspondence Address: THELEN REID BROWN RAYSMAN & STEINER LLP, P. O. BOX 640640, SAN JOSE, CA, 95164-0640, US

(21) Appl. No.: 11/661,871

(22) PCT Filed: Aug. 18, 2005
(86) PCT No.: PCT/JP05/15091

§ 371 Date: Mar. 2, 2007

(30) Foreign Application Priority Data
Sep. 6, 2004 (JP) 2004-259042

(51) Int. Cl. H01L 21/027; G03F 7/20; G03F 7/38

(52) U.S. Cl. 430/396; 430/449

(57) ABSTRACT

The formation of a resist pattern with high resolution using liquid immersion lithography, while concurrently preventing deterioration of the resist film during the liquid immersion lithography and deterioration of the used liquid itself, is possible through the use of a liquid which can be suitably used in a liquid lithography process in which the above resist film is exposed while being intervened by a liquid having a predetermined thickness and refractive index higher than air on at least a resist film on a route of allowing lithographic exposure light to reach to the resist film, thereby improving the resolution of a resist pattern. A liquid composed of a fluorine-based solvent that has a lowered hydrogen atomic concentration and exhibits sufficient transparency for the exposure light having a wavelength of no more than 200 nm employed in the exposure process, and that has a boiling point of 70 to 270° C., is used as an immersion liquid in liquid immersion lithography.

### TECHNICAL FIELD

The present invention relates to a liquid which can be suitably used in a liquid lithography process in which a resist film is exposed while being intervened by a liquid having a predetermined thickness and refractive index higher than air on at least a resist film on a route allowing lithographic exposure light to reach to the resist film, thereby improving the resolution of the resist pattern, and to a method for forming a resist pattern using such an immersion liquid.

### BACKGROUND ART

Lithography methods have been frequently used for the production of fine structures in various kinds of electronic devices, such as semiconductor devices and liquid crystal devices. However, as the device structures are miniaturized, resist patterns in lithography processes are also desired to be miniaturized.

In the advanced field, for example, a lithography process now allows the formation of a fine resist pattern having a line width of about 90 nm. However, finer pattern formation will be required in future.

For attaining the formation of such a fine pattern having a line width of less than 90 nm, a first point is to develop an aligner and a resist corresponding thereto. Common factors to consider for developing the aligner include shortening of wavelengths of optical sources such as F2 laser, EUV (extreme UV light), electron beam, and X-ray and increases in numerical aperture (NA) of lens.

However, the shortening of optical wavelength may require a new expensive aligner. In addition, even the resolution increases, a disadvantage of lowering a focal depth width occurs at high NA due to a trade-off relationship between the resolution and the focal depth width.

Recently, as a lithography technology for allowing such problems to be solved, a method known as a liquid immersion lithography process has been reported (e.g., Non-Patent Documents 1, 2, and 3). In this process, a liquid such as pure water or a fluorine-based inert liquid (immersion liquid) lies in predetermined thickness on at least a resist film between a lens and the resist film. In this method, the space of an exposure light path conventionally filled with inert gas such as air or nitrogen is replaced with a liquid having a larger refractive index (n), for example pure water to attain high resolution without a decrease in focal depth width in a manner similar to the use of a light source of shorter wavelength or a high NA lens even if the optical source having the same exposure wavelength is employed.

Such liquid immersion lithography has been remarkably noticed because the use thereof allows a lens implemented in the existing device to realize the formation of a resist pattern excellent in higher resolution property as well as excellent in focal depth in low costs.

(Non Patent Document 1) Journal of Vacuum Science & Technology B (J. Vac. Sci. Technol. B) (Issued country: U.S.A.), vol. 17, No. 6, pages 3306-3309, 1999.

(Non Patent Document 2) Journal of Vacuum Science & Technology B (J. Vac. Sci. Technol. B) (Issued country: U.S.A.), vol. 19, No. 6, pages 2353-2356, 2001.

(Non Patent Document 3) Proceedings of SPIE (Issued country: U.S.A.), Vol. 4691, pages 459-465, 2002.

### DISCLOSURE OF THE INVENTION

In the liquid immersion lithography process as described above, inert water such as pure water and deionized water, and perfluoro ether have been proposed as immersion liquids that may be used. In light of the cost, ease of handling and the like, inert water is very promising, however, the resist film may be permeated by the liquid because the resist film is brought into directly contact with the immersion liquid in exposure. Therefore, it is necessary to examine whether the resist composition that has been used conventionally can be applied as it is.

The resist composition, which has been commonly used in the art, is a composition established by widely investigating any of the potential resins in terms of the most essential characteristics, such as having transparency to exposure light. Such a resist composition is a composition superior in various resist characteristics including: transparency to exposure light, rectangularity of patterns, developing ability, and preservation stability, which has been established by expending many development resources. Furthermore, among these compositions, a lot of compositions exist which are excellent in a variety of resist properties such as transparency for exposure light, development, and stability during storage, with the exception of resistance to immersion liquid.

In addition, even if the abovementioned resist film appropriate to the liquid immersion exposure is used, it has been confirmed that the liquid immersion exposure deteriorates the quality, and yield of good products, as compared to the exposure through an air layer.

The adequacy of a resist film to liquid immersion lithography can be evaluated on the basis of the following assay.

In other words, for evaluating the abilities of liquid immersion lithography to form resist patterns, it is considered sufficient to confirm the following three items: (i) the capabilities of an optical system based on the liquid immersion lithography process; (ii) influences of a resist film on an immersion liquid, and (iii) denaturation of the resist film by the immersion liquid.

In principle, as long as no light propagation loss, such as light reflection on the surface of water and the boundary of water with the surface of a photographic plate occurs, no problem occurs with respect to the above item (i). It is evident from assuming, for example, cases in which the photographic plate having a water-proof surface is immersed into water and the surface is then exposed to patterning light. In this case, the light propagation loss can be easily settled by adequately defining an incident angle of exposure light. Therefore, regardless of a resist film, a photographic plate, or an image formation screen, which is provided as an exposure target, no variation may occur in optical properties as long as each of them is inactive to an immersion liquid, or as long as those are prevented from any influence from the immersion liquid and exerting no influence on the immersion liquid. Therefore, the present item does not require any additional conformation experiment.

With respect to item (ii), the immersion liquid influences the resist film, specifically by allowing the components of the resist film to escape into the liquid, to change the refractive index of the immersion liquid. A change in the refractive index of the immersion liquid may lead to a change in the optical resolution properties of the pattern exposure. This is true based on theory without any experimentation. Thus, the present item can be sufficiently confirmed from the fact that the components of the immersion liquid escape into the immersion liquid, the composition of the immersion liquid is changed, or the refractive index is changed when it is immersed therein. Therefore, it is not necessary to confirm the resolution by actually carrying out irradiation of patterning light and development.

Conversely, when the resist film in the immersed liquid is exposed to patterning light and then developed to confirm its resolution properties, the quality of the resolution may be confirmed. However, it is hardly defined as to whether the cause is related to any influence of deterioration in the quality of the immersion liquid on the resolution properties thereof, any influence on the deterioration in the quality of the resist material on the resolution properties thereof, or both.

With respect to the item (iii) where the resolution properties of the resist film is deteriorated by deterioration of the resist film in the immersion liquid, it is sufficient to carry out an evaluation test for “performing a process of showering the resist film with the immersion liquid after exposure and then carrying out development, followed by testing the resolution properties of the resulting resist patterns”. Besides, in this evaluation process, the immersion liquid is directly poured on the resist film, so that the conditions of liquid immersion may be more severe. With respect to such a fact, when the test of exposure in complete immersion is carried out, a cause of a change in resolution properties is hardly defined whether it is due to an influence of deterioration of the immersion liquid, an influence of deterioration of the resist film with the immersion liquid, or both influences.

The above phenomena (ii) and (iii) are one and the same, so that these phenomena can be figured out by confirming the degree of deterioration of the resist film with the immersion liquid.

Based on such an analysis, the suitability of the presently-proposed resist film to liquid immersion lithography as described above can be confirmed by an evaluation test of “performing a process of showering the resist film with the immersion liquid after exposure and then carrying out development, followed by testing the resolution properties of the resulting resist patterns” (hereinafter, referred to as “Evaluation Test 1”). Furthermore, it was also confirmed by carrying out an evaluation test that simulates an actual production process with a “two-beam interference process” using interference light through a prism instead of exposure patterning light and arranging a sample in liquid immersion, followed by developing an image (hereinafter, referred to as “Evaluation Test 2”). Furthermore, the relationship between the resist film and the immersion liquid can be confirmed by using a quartz-crystal oscillator method (a method for measuring a film thickness where the film thickness is detected on the basis of a change in weight by a quarts-crystal microbalance) as a method for measuring a trace level of a change in film thickness (hereinafter, referred to as “Evaluation Test 3”).

As described above, many development resources are needed to produce a new resist film suited for liquid immersion lithography. On the other hand, it has been ascertained that there exist resist compositions having characteristics suited for liquid immersion lithography among the resist compositions that have been currently proposed, either in their current form or by way of some modification to the composition, although the quality may suffer to some extent. In addition, it has also been ascertained that there are many resist films that exhibit fine and high resolution in lithography carried out by conventional exposure via an air layer even in the case of resist films that do not exhibit sufficient pattern resolution when used in liquid immersion lithography because of deterioration caused by the immersion liquid (pure water).

The present invention has been made in consideration of the abovementioned problem inherent to the prior art and intends to provide an immersion liquid having a high refractive index, which can be correspondingly applied to a resist film made of the conventional resist composition established by expending many development resources. Specifically, the problem to be solved by the present invention is the formation of a resist pattern with high resolution using liquid immersion lithography, while concurrently preventing deterioration of the resist film during the liquid immersion lithography and deterioration of the used liquid itself, through the use of a liquid that exhibits sufficient transparency for the exposure light, preferably also for light of short-wavelength of no more than 200 nm, along with lower volatilization at the temperature of the exposure step, and has a characteristic enabling easy removal from the resist film following the exposure, as the immersion liquid for use in liquid immersion lithography without the use of water.

In order to solve the abovementioned problems, the immersion liquid for the liquid immersion lithography process according to the present invention is characterized by being an immersion liquid that exhibits transparency for the exposure light used in the liquid immersion lithography process, and being composed of a fluorine-based solvent that is substantially inert against the resist film subjected to the exposure process, in which the hydrogen atomic concentration in the fluorine-based solvent is lowered.

Moreover, the method for forming a resist pattern according to a first aspect of the present invention is a process in which a liquid immersion lithography process is used, and is characterized by including a step of forming at least a photoresist film on a substrate, a step of directly arranging the immersion liquid on the resist film, a step of selectively exposing the resist film via the immersion liquid, a step of subjecting the resist film to a heat treatment as needed, and a step of developing the resist film to obtain the resist pattern.

Furthermore, the method for forming a resist pattern according to a second aspect of the present invention is a process in which a liquid immersion lithography process is used, and is characterized by including a step of forming at least a photoresist film on a substrate, a step of forming a protective film on the resist film, a step of directly arranging the immersion liquid on the protective film, a step of selectively exposing the resist film via the immersion liquid and the protective film, a step of subjecting the resist film to a heat treatment as needed, and a step of developing the resist film to obtain the resist pattern.

In the above configuration, the liquid immersion lithography process may be preferably configured such that the resolution of a resist pattern can be improved by exposure while allowing a liquid having a predetermined thickness and a refractive index higher than that of air to be placed on at least the resist film in a pathway along which exposure light for lithography reaches to a resist film.

According to the present invention, even though the resist film is formed using any conventional resist composition, and even in the case in which a short-wavelength light of no more than 200 nm is used as the exposure light, it is possible to obtain a resist pattern having a high sensitivity, capable of providing an excellent resist pattern profile shape, and being highly accurate without worsening phenomena such as causing T-top shaping of the resist pattern, embossing impression of the resist pattern surface, fluctuation of the pattern, and stringing phenomenon in the liquid immersion lithography step. Also, in the case in which the protective film is formed on the resist film, and the immersion liquid of the present invention is arranged on the protective film, an excellent resist pattern can be formed.

Therefore, when the immersion liquid of the present invention is used, a highly accurate resist pattern can be efficiently formed in the liquid immersion lithography process by using the short-wavelength light of no more than 200 nm as the exposure light.

### BRIEF DESCRIPTION OF THE DRAWINGS

FIG. 1 shows an NMR chart of a commercial product of perfluorotributylamine having a boiling point of 174° C.;

FIG. 2 shows an NMR spectrum of a product having a lowered hydrogen atomic concentration in perfluorotributylamine having a boiling point of 174° C.;

FIG. 3 shows a UV absorption chart of a commercial product of perfluorotributylamine having a boiling point of 174° C., for light in the range of the wavelength of 200 nm to 600 nm; and

FIG. 4 shows a UV absorption chart of a product with a lowered hydrogen atomic concentration in perfluorotributylamine having a boiling point of 174° C., for the light in the range of the wavelength of 200 nm to 600 nm.

### PREFERRED MODE FOR CARRYING OUT THE INVENTION

The immersion liquid according to the present invention is characterized by being transparent even when short-wavelength light of no more than 200 nm is used as the exposure light in the liquid immersion lithography process. This transparency may be attained by lowering the hydrogen atomic concentration in the fluorine-based liquid that constitutes the immersion liquid.

The phrase “immersion liquid being transparent for the exposure light” referred to herein means that when the exposure light passes through the immersion liquid having a thickness commonly used in the liquid immersion lithography (approximately 1 cm), the light first reaches the top face, and then pass through to the bottom face of the immersion liquid. When the incident light does not reach the bottom face, the immersion liquid is deemed to be non-transparent. As described above, the incident light that reaches the bottom face of the immersion liquid is necessary for the exposure of the resist film. Because the intensity of the light that reaches the resist film, which determines the exposure of the resist film, is dependent on the sensitivity of the resist film used, it cannot be determined unambiguously.

Also, the phrase “hydrogen atomic concentration in the fluorine-based liquid” referred to herein means a total concentration derived by adding the concentration of hydrogen atoms in carbon atom-hydrogen atom bonds included in the composition of the fluorine-based liquid to the concentration of free protons and the like existing in the liquid. Therefore, the hydrogen atomic concentration being 1 ppm suggests that the concentration of the aforementioned impurities is not higher than 1 ppm. In the present invention, this hydrogen atomic concentration is preferably no more than 1 ppm, and more preferably 0.5 ppm.

The fluorine-based liquid that constitutes the immersion liquid of the present invention is characterized by having a boiling point of 70 to 270° C.

The immersion liquid composed of the fluorine-based liquid having a boiling point falling within such a range can provide the excellent benefits of: (i) being inert to the resist film formed with any conventional resist composition, thereby avoiding deterioration of the resist film; (ii) being capable of maintaining the components of the immersion liquid itself always unchanged throughout time periods before, after and during the exposure because elution of the components of the resist film is prohibited, thereby enabling a stable refractive index for the exposure light constant, and presentation of stable and favorable light paths of the exposure light; (iii) being capable of preventing alteration of the ratio of the components of the immersion liquid itself resulting from volatilization of the liquid, and alteration of the liquid level in the exposure step carried out at around room temperature because the boiling point is 70° C. or higher, thereby enabling maintenance of a stable and favorable light path of the exposure; and (iv) being capable of readily and sufficiently carrying out removal of the immersion liquid from the resist film after completing the liquid immersion lithography by a simple method such as drying at room temperature; spin drying; drying by heating; blowing compressed nitrogen or the like, because the boiling point is no more than 270° C. In addition, because the immersion liquid exhibits a high solubility toward gases such as oxygen and nitrogen, the generation of microbubbles, nanobubbles or the like, which may have an adverse effect on lithography, can be effectively diminished.

The fluorine-based liquid suited for the immersion liquid of the present invention has, as described above, a boiling point of 70 to 270° C., and more preferably 80 to 220° C. Specifically, such a fluorine-based liquid may be exemplified by a perfluoroalkyl compound. Examples of this perfluoroalkyl compound include perfluoroalkyl ether compounds and perfluoroalkylamine compounds.

Still further, specific examples of the perfluoroalkyl ether compound include perfluoroalkyl cyclic ethers such as perfluoro (2-butyl-tetrahydrofuran) (boiling point: 102° C.), and the like. Examples of the perfluoroalkylamine compound include perfluorotripropylamine N(C₃F₇)₃ (boiling point: 130° C.), perfluorotributylamine N(C₄F₉)₃ (boiling point: 174° C.), perfluorotripentylamine N(C₅F₁₁)₃ (boiling point: 215° C.), perfluorotrihexylamine N(C₆F₁₃)₃ (boiling point: approximately 255° C.), and the like. Such fluorine-based liquids highly purified to have a hydrogen atomic concentration of no more than 1 ppm are preferred concerning high transparency for the exposure light.

Furthermore, among them, those exhibiting low absorption of the exposure light and having suitable volatility as the liquid immersion liquid are preferred. Preferable examples of these include perfluorotripropylamine and perfluorotributylamine.

As described above, in non patent documents that are prior art documents relating to liquid immersion lithography, perfluoroalkyl polyether has been proposed as the immersion liquid. In developing the present invention, the present inventors investigated the practical applicability of a variety of commercial products of perfluoroalkyl polyether as the immersion liquid from the view point of the abovementioned developmental aspects. Consequently, the present inventors ascertained that there was no immersion liquid having a boiling point of no more than 270° C., which was one of the characteristic criteria deemed necessary, and hence removal of the immersion liquid carried out after completing the exposure could not be satisfactorily perfected by the simple method as described above, whereby formation of the resist pattern was impossible due to the residual materials of the immersion liquid.

In addition, these perfluoroalkyl polyethers exhibit a great degree of dispersion of the molecular weight, and such a characteristic is a factor limiting the stabilization of the refractive index of the exposure light and could ultimately account for the loss in optical stability under the exposure conditions.

The degree of dispersion of the molecular weight is believed to be comparatively small in the immersion liquid of the present invention, whereby it is expected to be a suitable liquid in terms of not impairing optical stability.

In the present invention, any resist film obtained using a resist composition that has been conventionally employed can be used, without experiencing any particular related limitations. More specifically, conventionally employed resist compositions for positive or negative photoresist can be used as the resist composition for the liquid immersion lithography process of the present invention. This aspect also constitutes the most important feature of the present invention. Particularly, the immersion liquid of the present invention is intended to attain transparency for short-wavelength light of no more than 200 nm by lowering the atomic concentration of hydrogen bound to its structural skeleton; therefore, a known F₂ resist composition that exhibits high sensitivity against a F₂ laser beam is preferably used as the resist composition. Known examples of such an F₂ resist composition include compositions which comprises a fluorine-containing polymer as a resin component.

Next, the process for forming a resist pattern by liquid immersion lithography using the immersion liquid of the present invention is explained.

The first process according to the present invention is a process for forming a resist pattern in which a liquid immersion lithography process is used, and is characterized by including: forming at least a photoresist film on a substrate; directly arranging the immersion liquid on the resist film; selectively exposing the resist film via the immersion liquid; subjecting the resist film to a heat treatment as needed; and then developing the resist film to form the resist pattern.

Furthermore, the second process according to the present invention is a process for forming a resist pattern in which a liquid immersion lithography process is used, and is characterized by including: forming at least a photoresist film on a substrate; forming a protective film on the resist film; directly arranging the immersion liquid on the protective film; selectively exposing the resist film via the immersion liquid and the protective film; subjecting the resist film to a heat treatment as needed; and then developing the resist film to form the resist pattern.

In the first process, after applying a commonly used resist composition with a spinner or the like on a substrate such as a silicon wafer, prebaking (PAB treatment) is carried out.

A two-layer laminate can be also produced in which an organic or inorganic antireflection film is provided between the substrate and the applied layer of the resist composition.

The foregoing steps can be carried out with a known procedure. It is preferred that conditions and the like of operation are freely determined depending on the composition and characteristics of the used resist composition.

Next, the resist film on the substrate is brought into contact with the aforementioned immersion liquid. The contact is not particularly limited, but may refer to immersion of the substrate in the immersion liquid or direct placement of the immersion liquid on the resist film.

Exposure is selectively executed via a desired mask pattern onto the resist film on the substrate in such a state of immersion. Therefore, the exposure light shall reach the resist film after passing through the immersion liquid in this step.

Although the resist film is in direct contact with the immersion liquid in this step, the immersion liquid is inert to the resist film as described above; therefore, the resist film is not deteriorated, nor is the immersion liquid itself by the resist film, whereby avoiding deterioration of optical characteristics thereof such as refractive index and the like. Furthermore, because the boiling point is at least 70° C., and the temperature in the exposure step is approximately room temperature, alteration of the concentration and lowering of the liquid level due to volatilization can be avoided. Accordingly, a light path that remains stable along with constant refractive index and transparency may be provided.

The wavelength used in the exposure in this instance is not particularly limited, but a radial ray such as an ArF excimer laser, KrF excimer laser, F₂ laser, EUV (extreme ultraviolet ray), VUV (vacuum ultraviolet ray), electron ray, X ray, or soft X ray can be used. Because the immersion liquid of the present invention is intended to attain transparency for the short-wavelength light of no more than 200 nm, the choice as to which ray having the aforementioned wavelength should be used may be determined predominantly depending on the characteristics of the resist film.

After completing the exposure step under the liquid immersion state in which the immersion liquid is used, for example, the substrate is taken out from the immersion liquid, and then the immersion liquid is removed from the substrate by a means such as drying at room temperature, spin drying, drying by heating, or blowing compressed nitrogen. Because the immersion liquid has a boiling point of at most 270° C., the immersion liquid can be removed completely from the resist film by such treatments.

Next, the exposed resist film is subjected to PEB (post exposure baking), followed by a development treatment using an alkaline development liquid including an aqueous alkaline solution. Alternatively, post baking may be carried out following the development treatment. Then, the rinse may be carried out, preferably using pure water. In the rinse with water, for example, water is poured or sprayed on the substrate surface while rotating the substrate, whereby the development liquid on the substrate and the resist composition dissolved by the development liquid are washed away. Thereafter, drying is carried out to obtain the resist pattern provided by patterning of the resist film to have the corresponding shape of the pattern mask.

The second process is similar to the first process except that a protective film is provided between the resist film and the immersion liquid.

The immersion liquid of the present invention is useful for expanding the versatility of liquid immersion lithography processes for resists in which a resin having low aqueous liquid immersion resistance as described above is used; however, it can also be applied preferably in processes in which the protective film is provided on such a resist film. As the application liquid for protective film formation used in providing the protective film, an aqueous solution containing a water soluble or alkali soluble film forming component is preferred.

This water soluble film forming component is not particularly limited, as any component may be used as long as it has water solubility or alkaline solubility and transmittance of the exposure light. For example, a component having characteristics of i) being capable of forming a more uniform film coating by a conventional application means such as spin coating, ii) being free from formation of a deteriorated layer in between the photoresist film layers even when applied on the photoresist film, iii) being capable of sufficiently transmitting the active light ray, iv) being capable of forming a coated film having a low absorption coefficient and high transparency, and the like may be preferably used.

By forming the resist pattern in this manner, a resist pattern with minute line width, particularly a line and space pattern with small pitch, can be produced with improved resolution. The pitch in the line and space pattern referred to herein means the total distance of the resist pattern width and space width in a cross line direction of the pattern.

### EXAMPLES

Hereinafter, examples of the present invention are explained. In advance, an experimental example demonstrating that transparency for the short-wavelength light of no more than 200 nm can be attained by lowering the hydrogen atomic concentration in the fluorine-based liquid, having a boiling point of 70 to 270° C., is presented. Thereafter, an example and a comparative example are presented. The example presented below is merely an illustration to demonstrate the present invention, but not as to in anyway limit the present invention thereto.

### Experimental Example

With respect to a commercial product (with hydrogen atom concentration not lowered), and a product with a lowered hydrogen atomic concentration of perfluorotributylamine having a boiling point of 174° C., NMR measurement and UV absorption measurement were carried out on each.

The NMR measurement was carried out on a proton NMR at 400 MHz.

The UV absorption measurement was carried out using an ultraviolet and visible spectrophotometer “UV-2500PC” (manufactured by Shimadzu Corporation).

The charts thus obtained are shown in the Figure.

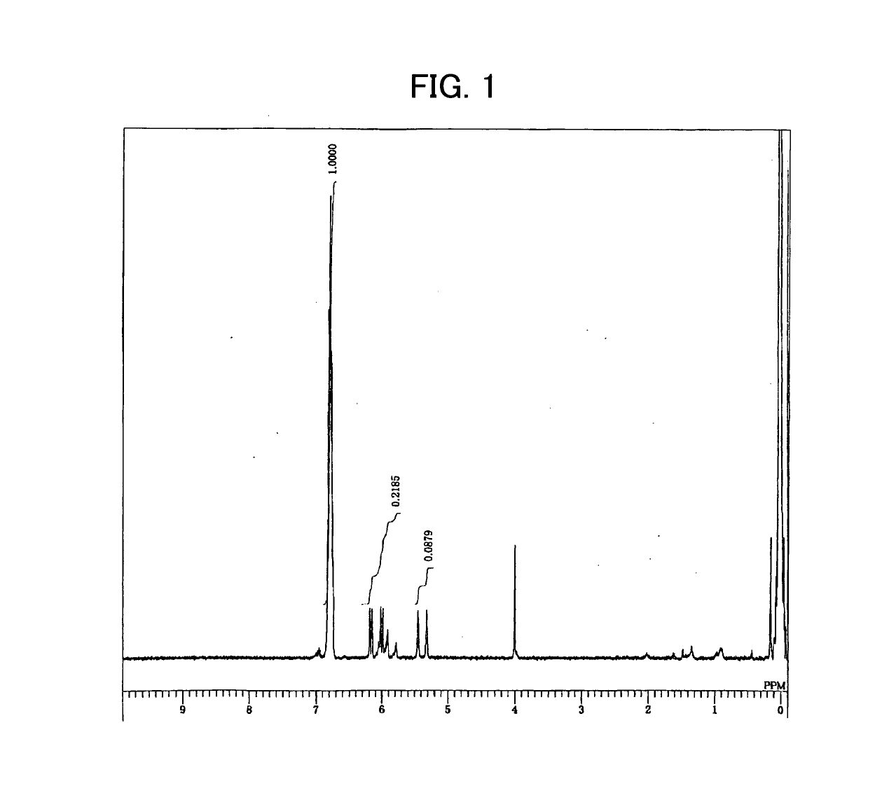

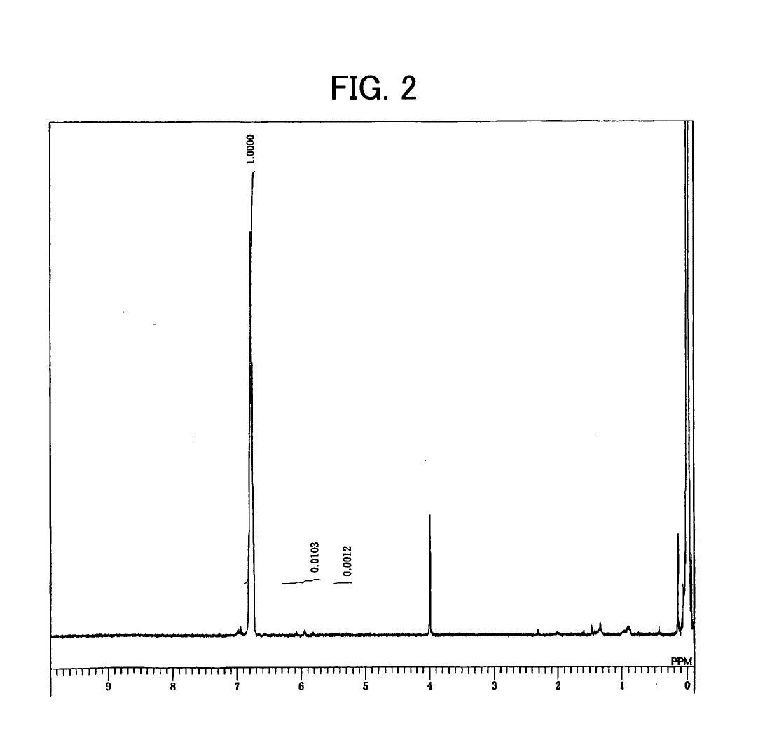

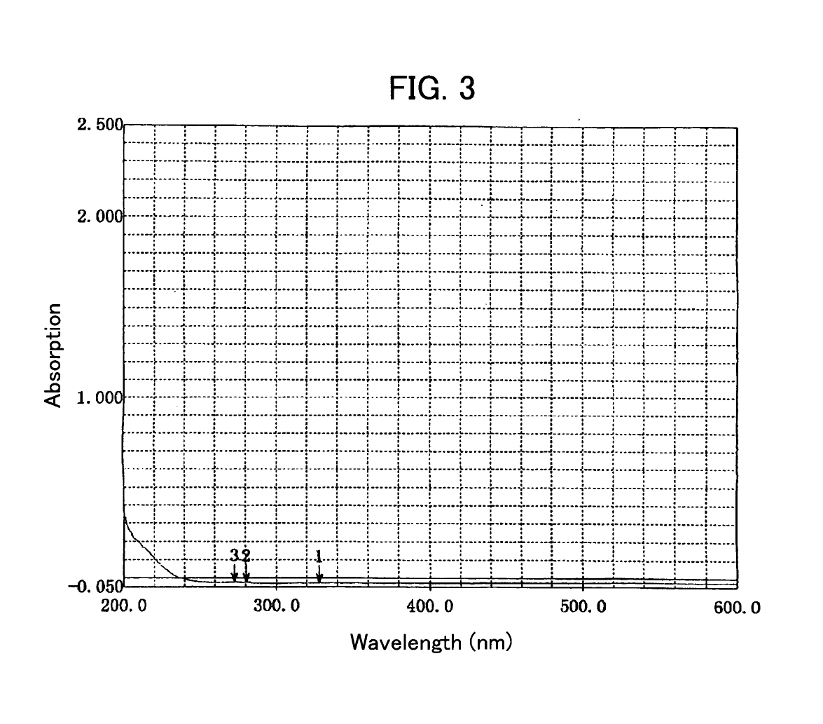

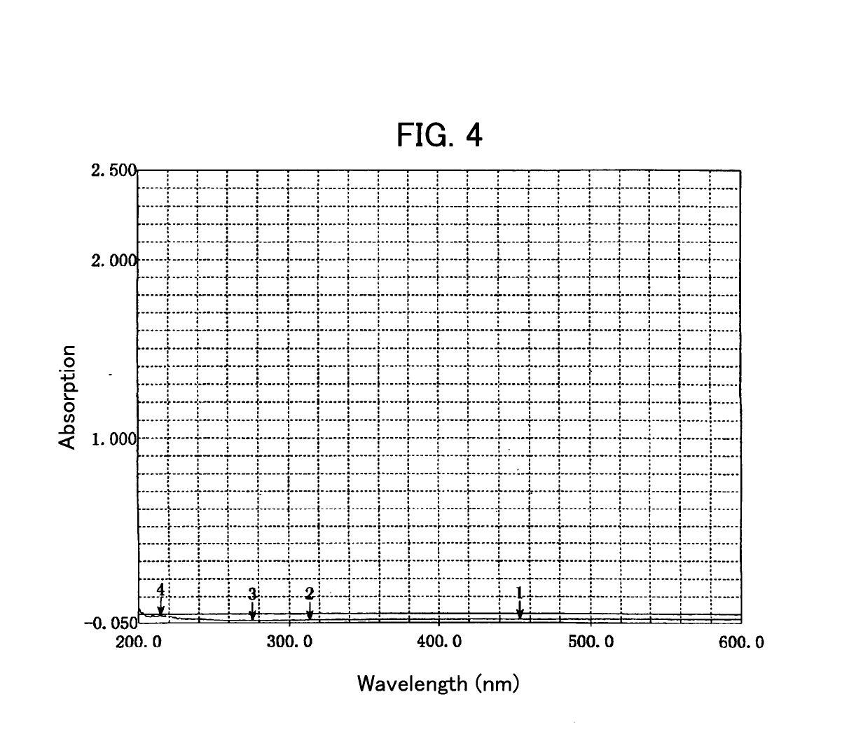

FIG. 1 shows an NMR spectrum of the commercial product. FIG. 2 shows an NMR spectrum of the product with a lowered hydrogen atomic concentration. FIG. 3 shows a UV absorption spectrum of the commercial product, for light in the wavelength range of 200 nm to 600 nm. FIG. 4 shows a UV absorption spectrum of the product with a lowered hydrogen atomic concentration according to the present invention shown in FIG. 2, for light in the wavelength range of 200 nm to 600 nm.

The results of the NMR measurement reveal that the hydrogen atomic concentration in perfluorotributylamine was lowered. Moreover, the results of the UV absorption measurement reveal that the absorption of the exposure light of 200 nm was reduced.

### Example

The positive type resist composition was obtained by homogenously dissolving 100 parts by mass of a resin component represented by the following general formulae (45) and (46), 2.0 parts by mass of triphenyl sulfonium nonafluorobutane sulfonate as an acid generator, and 0.6 parts by mass of tridodecylamine as an amine, in a propylene glycol monomethyl ether acetate solution, to give a solid content of 8.5% by parts by mass.

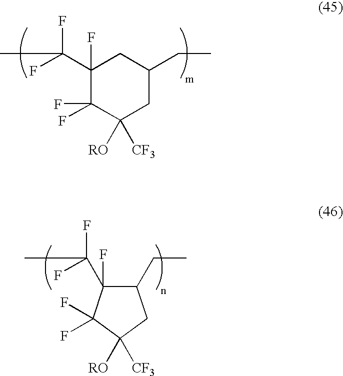

Formation of the resist pattern was conducted using the positive type resist composition produced as described above. First, an organic antireflection film composition “AR-19” (trade name, manufactured by Shipley Company) was applied on a silicon wafer using a spinner, and an organic antireflection film having a film thickness of 82 nm was formed by drying through baking on a hot plate at 215° C. for 60 seconds. Then, the positive type resist composition obtained as described above was applied on the antireflection film using a spinner, and a resist layer having a film thickness of 102 nm was formed on the antireflection film by drying through prebaking on a hot plate at 95° C. for 90 seconds.

Thereafter, liquid immersion lithography was performed using an experimental apparatus manufactured by Nikon Corporation as Evaluation Test 2. Using a prism and a fluorine-based solvent including perfluorotripropylamine, an experiment by two-beam interference of 193 nm (two-beam interference experiment) was conducted. A similar method is also disclosed in Non Patent Document 2, and is known as a method by which a line and space pattern can be readily obtained in laboratory scale.

In the liquid immersion lithography in this example, a fluorine-based solvent layer according to the chart shown in FIG. 2 was formed as the immersion solvent between the upper face of the protective film and the interior face of the prism.

The exposure value was selected such that the line and space pattern could be obtained in a stable manner. After the exposure via a mask, the fluorine-based liquid was wiped off, and then a PEB treatment was carried out under a condition at 115° C. for 90 seconds.

Thereafter, a development treatment was further carried out in a 2.38% by mass aqueous tetramethylammonium hydroxide solution at 23° C. for 60 seconds.

As a result, it was revealed that a 65 nm line and space (1:1) was obtained.

### Comparative Example

Formation of the resist pattern was conducted by a similar operation to Example 1, except that DEMNUM S-20 (trade name, manufactured by Daikin Industries, Ltd.), which is a perfluoroalkyl polyether compound having a vapor pressure at 200° C. of 10⁻¹ torr or lower, i.e., having an extremely low volatility, was used as the immersion liquid.

Consequently, the immersion liquid could not be removed by the spin drying step carried out subsequent to the exposure step, even though a long period of time had elapsed. Also, the removal could not be perfected even through other means such as a heating step and a blowing compressed nitrogen step were carried out. Accordingly, the perfluoropolyether compound, which was the immersion liquid, remained on the resist film, thereby preventing the pattern formation of the resist.

### INDUSTRIAL APPLICABILITY

As described herein above, the immersion liquid according to the present invention is advantageous in terms of the formability of a highly accurate resist pattern with high sensitivity and excellent resist pattern profile shape through the use thereof in the liquid immersion lithography step. In particular, it is suited for producing the resist pattern without causing worsening phenomena such as T-top shaping of the resist pattern, embossing impression of the resist pattern surface, fluctuation of the pattern, and a stringing phenomenon in the liquid immersion lithography step, even though the resist film may be composed of any conventional resist composition, and further, even in the case in which the short-wavelength light of no more than 200 nm is used as the exposure light.

Moreover, the process for forming the resist pattern in which the immersion liquid according to the present invention is used is advantageous in that an excellent resist pattern can be produced in both cases where the immersion liquid is directly arranged on the resist film, and where the protective film is formed on the resist film, and the immersion liquid of the present invention is arranged on the protective film.

1. An immersion liquid for the liquid immersion lithography process, which exhibits transparency for the exposure light used in the liquid immersion lithography process, and comprises a fluorine-based solvent which is substantially inert against a resist film subjected to the exposure process, wherein the hydrogen atomic concentration in the fluorine-based solvent is lowered.

2. The immersion liquid according to claim 1, which exhibits transparency for light of wavelength of no more than 200 nm, by lowering the hydrogen atomic concentration in the fluorine-based solvent.

3. The immersion liquid according to claim 1, wherein the hydrogen atomic concentration is no more than 1 ppm.

4. The immersion liquid according to claim 3, wherein the hydrogen atomic concentration is no more than 0.5 ppm.

5. The immersion liquid according to claim 1, wherein the fluorine-based liquid has a boiling point of 70 to 270° C.

6. The immersion liquid according to claim 1, wherein the fluorine-based liquid comprises perfluoroalkyl compounds.

7. The immersion liquid according to claim 6, wherein the perfluoroalkyl compounds are perfluoroalkyl ether compounds.

8. The immersion liquid according to claim 6, wherein the perfluoroalkyl compounds are perfluoroalkylamine compounds.

9. The immersion liquid according to claim 1, wherein the liquid immersion lithography process comprises the steps of exposing the resist film while being intervened by a liquid having a predetermined thickness and refractive index higher than air on at least a resist film on a route allowing lithographic exposure light to reach to the resist film, thereby improving the resolution of the resist pattern

10. A method for forming a resist pattern with a liquid immersion lithography process, comprising the steps of:
forming at least a resist film on a substrate;
directly arranging an immersion liquid on the resist film, where the immersion liquid exhibits transparency for the exposure light used in the liquid immersion lithography process, and comprises a fluorine-based solvent which is substantially inert against a resist film subjected to the exposure process, wherein the hydrogen atomic concentration in the fluorine-based solvent is lowered;
selectively exposing the resist film to light through the immersion liquid; and
forming a resist pattern by developing the resist film.

11. A method for forming a resist pattern with a liquid immersion lithography process, comprising the steps of:
forming at least a resist film on a substrate;
forming a protective film on the resit film;
directly arranging an immersion liquid on the protective film, where the immersion liquid exhibits transparency for the exposure light used in the liquid immersion lithography process, and comprises a fluorine-based solvent which is substantially inert against a resist film subjected to the exposure process, wherein the hydrogen atomic concentration in the fluorine-based solvent is lowered;
selectively exposing the resist film to light through the immersion liquid and the protective film; and
forming a resist pattern by developing the resist film.
